(19) United States
(12) Patent Application Publication
(10) Pub. No.: US 2011/0182010 A1
(43) Pub. Date: Jul. 28, 2011

(54) DISPLAY HOLDER FOR FLAT PANEL DISPLAY

(76) Inventor: Johannes Franciscus Adrianus Schouten, Maastricht (NL)

(21) Appl. No.: 13/001,506

(22) PCT Filed: Jun. 26, 2009
(86) PCT No.: PCT/EP2009/058012

§ 371 Date: Apr. 18, 2011

(30) Foreign Application Priority Data
Jun. 27, 2008 (EP) 08159281.8

(51) Int. Cl. H05K 7/00; H05K 7/14; F16B 47/00; B23P 17/04

(52) U.S. Cl. 361/679.01; 248/205.1; 248/205.3; 29/428

(57) ABSTRACT

A display holder (10, 20, 30) is provided for coupling a frame (43) of a flat panel display (40) to a display panel (41) of the flat panel display (40), the display holder (10, 20, 30) comprising a support surface (11, 21, 31) for supporting the display panel (41) and for attaching the display holder (10, 20, 30) to the display panel (41), the display holder (10, 20, 30) being constructed for being received by a hole in the frame (43), which hole is present in the frame (43) for receiving the display holder (10, 20, 30). Also a display (40) comprising such a display holder (10, 20, 30), a frame (43) with holes for receiving such a display holder (10, 20, 30) and methods for assembling a display (40) using such a display holder (10, 20, 30) are provided.

### FIELD OF THE INVENTION

This invention relates to flat panel displays and to a method for assembly of flat panel displays.

### BACKGROUND OF THE INVENTION

Flat panel displays are used in a large variety of applications and use many different techniques for displaying images. TVs, computer monitors and cellular phone displays often use LCD technology, where a backlight shines on a display surface through a layer of liquid crystal molecules of which the alignment can be manipulated. In other LCD applications, the backlight is omitted and a back reflector in combination with environmental light provides the light for the display. For TVs also plasma technology is used. Plasma displays use cells located between two glass panels and filled with electrically excitable gas. Electrophoretic displays, e.g. using E-ink, use micro capsules with positively and negatively charged particles having different colors. Electrophoretic displays are, e.g., often used for E-books, such as the iLiad of iRex Technologies.

The above mentioned and many other different flat panel display technologies share some problems in the assembly and usage of the displays. During assembly, a display panel has to be mounted on a frame. The display panel comprises one or more transparent plate typically made of glass, a layer with pixel elements (e.g. liquid crystals, gas filled cells or microcapsules), and some electronics or connection cables for connecting the pixel elements to the control electronics of the display. A usual way to attach the display panel to the frame is to glue the display panel to a flat part of the frame, which flat part is covered with some adhesive. Before attaching the display panel to the frame, the display panel first has to be aligned very carefully in order to ensure a proper working connection between the pixel elements and the control electronics of the display. When during the alignment of the display panel, the panel contacts the adhesive, the display panel may be fixed in a non-optimal position.

### OBJECT OF THE INVENTION

It is an object of the invention to provide something to make the mounting of the display panel on the frame less difficult.

### SUMMARY OF THE INVENTION

According to a first aspect of the invention, this object is achieved by providing a display holder for coupling a frame of a flat panel display to a display panel of the flat panel display, the display holder comprising a support surface for supporting the display panel and for attaching the display holder to the display panel, the display holder being constructed for being received by a hole in the frame, which hole is present in the frame for receiving the display holder.

The advantage of the use of this display holder is that placing the display holder in the frame hole and attaching the display panel to the support surface can be postponed until the display panel has been aligned. Unlike with the prior art assembly method described above, when using the display holder according to the invention there is no risk of the display panel getting attached to the frame during the alignment of the display panel. After alignment of the display panel, the display panel is attached by simply pushing, screwing or otherwise placing the display holder into the hole to make contact with the display panel.

In a preferred embodiment, the display holder further comprises a resilient element for coupling the display holder to the frame, the resilient element being arranged for absorbing shocks in a direction substantially parallel to the display panel.

An additional disadvantage of the above described prior art flat panel displays is that heavy impacts on the side of the screen may cause the display panel to break or to become misaligned. This is especially a problem for portable display applications, such as for laptops or E-books, which may fall on the floor while being used. By providing a resilient coupling between the frame and the display holders, this problem is solved. The shock caused by the impact is absorbed by the resilient element of the display holder. First, due to the shock, the display panel will move relative to the frame and then, the resilient element will bring the display panel back to its original position.

Preferably, the display holders are provided at three positions around a center of the display panel for preventing bending of the display panel in the event of shocks in a direction perpendicular to the display panel. This will prevent the display panel from breaking when receiving an impact caused by, e.g., someone pushing too hard on the screen or an object falling on the screen.

Preferably, the hole in the frame and the display holder are configured to be combined in two exchangeable modes; an operational mode, wherein the display holder is attached to the display panel and an assembly mode, wherein the display holder is not attached to the display panel.

This ensures easy assembly of the flat panel display. After aligning the display panel, only minor adjustments to the display holder (changing from assembly mode to operational mode) are required. Additionally, this makes it possible to release the display panel for, e.g., re-aligning the display panel or for repairing parts of the flat panel display. After the re-aligning or repair, the display holders may be replaced by new ones or may be attached to the display panel again.

According to a second aspect of the invention, a flat panel display is provided comprising at least one display holder according to the invention.

According to a third aspect of the invention, a frame is provided comprising at least one hole for receiving a display holder according to the invention.

According to a fourth aspect of the invention, a method for assembling a flat panel display is provided, using at least one display holder according to the invention. These and other aspects of the invention are apparent from and will be elucidated with reference to the embodiments described hereinafter.

### BRIEF DESCRIPTION OF THE DRAWINGS

In the drawings:

FIG. 1a shows a top view of a display holder according to the invention,

FIG. 1b shows a side view of the display holder of FIG. 1a,

FIG. 1c shows a top view of another display holder according to the invention,

FIG. 1d shows a side view of the display holder of FIG. 1c,

FIG. 2a shows a top view of a third display holder according to the invention,

FIG. 2b shows a side view of the display holder of FIG. 2a,

FIG. 2c shows a 3D view of the display holder of FIG. 2a,

FIG. 3 schematically shows a cross section of a display and display holder, when combined in an assembly mode,

FIG. 4 schematically shows a cross section of a display and display holder, when combined in a operational mode,

FIG. 5 indicates a preferred position for the display holders to be used in the flat panel display, and

FIG. 6, shows the flat panel display of FIG. 5, from a bottom view.

### DETAILED DESCRIPTION OF THE INVENTION

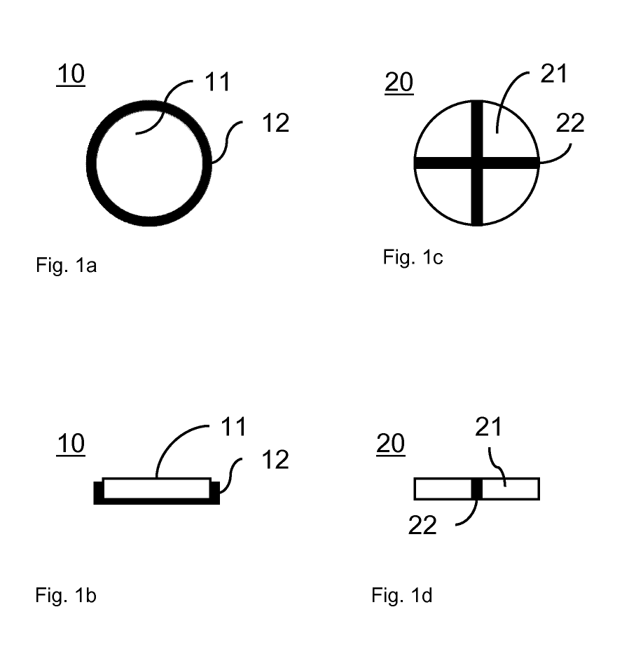

FIG. 1a shows a top view of a display holder 10 according to the invention. FIG. 1b shows a side view of the display holder 10 of FIG. 1a. The display holder 10 comprises a support surface 11 for supporting a display panel. The support surface 11 is a flat surface that may either be rigid or flexible. For example, plastics, metal or glass may be used for making the display holder part comprising the support surface 11. It is to be noted, that the display holder 10 is not necessarily circular shaped. Squares, triangles, pentagons, ovals or other shapes may be used as well. The support surface 11 is surrounded by a resilient element 12. Many different resilient materials may be used. For example, the resilient element 12 comprises rubber or a flexible plastic. An exemplary flexible plastic is Acrylonitrile Butadiene Styrene (ABS). In use, the support surface 11 is attached to the display panel. In a special embodiment, the support surface 11 and the resilient element 12 are made from the same flexible material. The support surface 11 may be fixed to the display panel by providing an adhesive on the support surface 11. For example, a double side adhesive tape may be used. A release liner may cover the adhesive in order to protect the support surface 11 before placement in the display. When the display holder 10 is installed, first the release liner is removed. Preferably, the support surface 11 is attached to the display panel in such a way that it remains possible to detach it without destructing the panel or display holder 10. The resilient element 12 couples the display holder 10 to the frame and absorbs shocks that may occur when, e.g., the display falls on the floor. Especially shocks in directions parallel to the display panel and support surface 11 will be absorbed very well.

FIG. 1c shows a top view of another display holder 20 according to the invention. FIG. 1d shows a side view of the display holder 20 of FIG. 1c. The support surface 21 and the resilient element 22 have the same function as the corresponding elements 11, 12 in the display holder 10 of FIGS. 1a and 1b. Thus, for this display holder 20, the same materials may be used. A difference with the display holder 10 of FIGS. 1a and 1b is that the resilient material is arranged in straight bars inside the support surface 21 instead of as a ring around it.

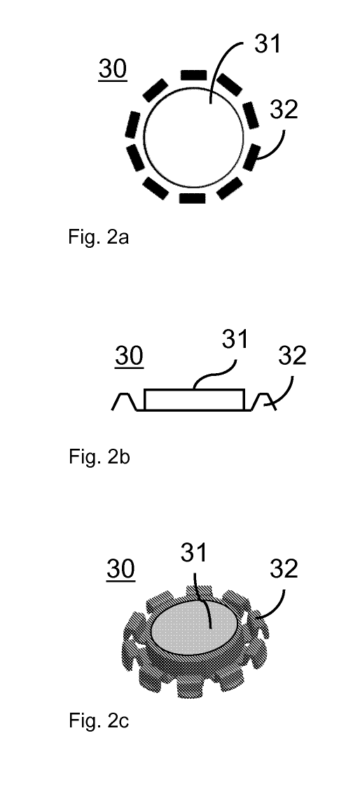

FIG. 2a shows a top view of a third display holder 30 according to the invention. FIG. 2b shows a side view and FIG. 2c shows a 3d view of the display holder 30 of FIG. 2a. Like in the previous figures, the support surface 31 is a circular surface, optionally covered with an adhesive. In this display holder 30, the resilient element is formed by a number of spring elements 32 surrounding the support surface 31. The spring elements may comprise flexible material or may comprise more rigid material (e.g. metal or rigid plastic) which becomes flexible due to the specific shape of the spring elements 32.

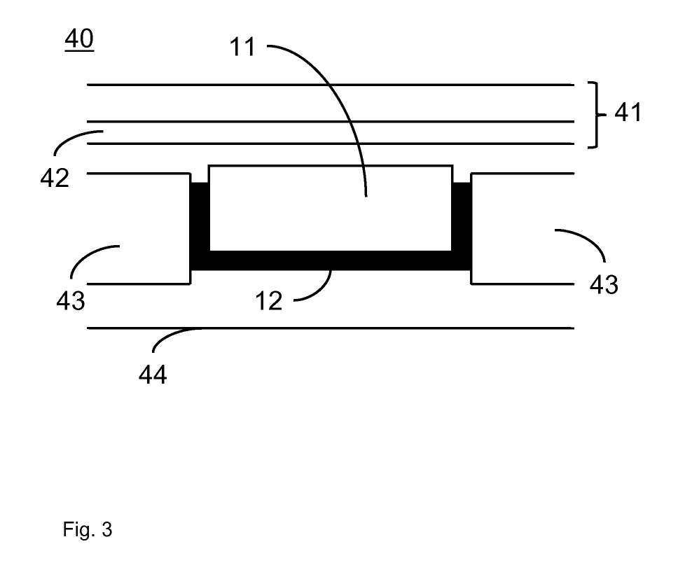

FIG. 3 schematically shows a cross section of a display 40 and display holder 10, when combined in an assembly mode. The display 40 comprises a display panel 41 and a layer with pixel elements (e.g. liquid crystals, gas filled cells or micro capsules). The display panel 41 also comprises contact elements for enabling coupling the pixel elements to the display control electronics. Optionally, the display panel includes a touch sensing panel 42, such as a Wacom panel in order to provide a touch screen user interface. Assembly of the display 40 may start with placing one or more display holders 10 in holes provided in the frame 43 especially for receiving such display holder 10. Optionally, this step is preceded by removing a release liner from the support surface 11 to expose the adhesive. The frame 43 and display holder 10 are combined in an assembly mode, making it possible for a display panel 41 to be moved relative to the frame 43 and the display holder 10. Then, the display panel 41 is placed, optionally together with the touch sensing panel 42, on the frame 43 and the panel 41 is aligned with the frame 43 such that all necessary electronic contacts can be made. When the display panel 41 is correctly aligned with the frame 43, the display holders are pushed or screwed further into the hole of the frame 43 in order to make contact with the display panel 41 and attach the support surface 11 to the display panel 41.

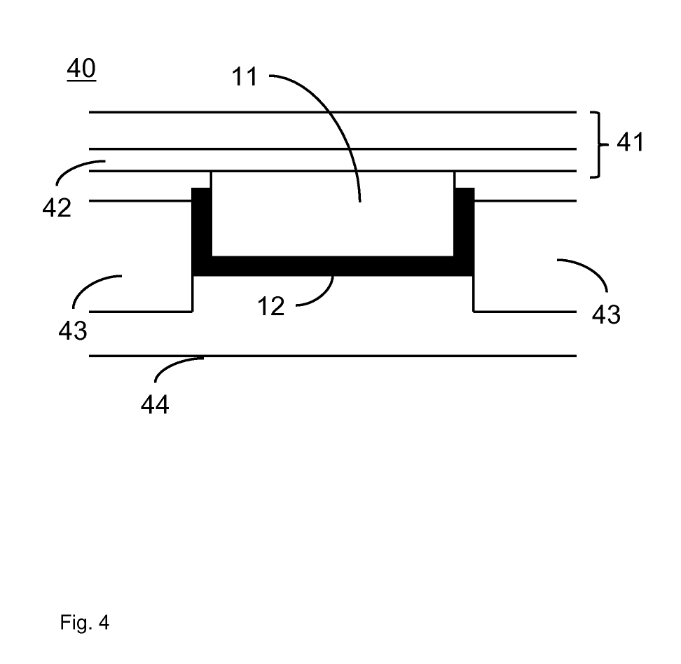

FIG. 4 schematically shows a cross section of a display 40 and display holder 10, when combined in a operational mode. In the operational mode, the alignment of the display panel 41 relative to the frame 43 is fixed. Due to the resilient properties of the resilient element 12, the alignment of the display panel 41 may change temporarily when the display 40 falls on the floor, or receives a shock for some other reason. Very soon after the shock, the resilient element 12 will bring the display panel 41 back to its correct position. By absorbing the shock, damage to the display panel is avoided.

Preferably, the attachment of the support surface 11 to the display panel 41 is such that it is possible to change from operational mode to assembly mode and vice versa. This enables re-alignment of the display panel and opening the display 40 for repair purposes. Depending on the adhesive used, it may be necessary to replace the adhesive after releasing the display holder 10 and before using the display holder again.

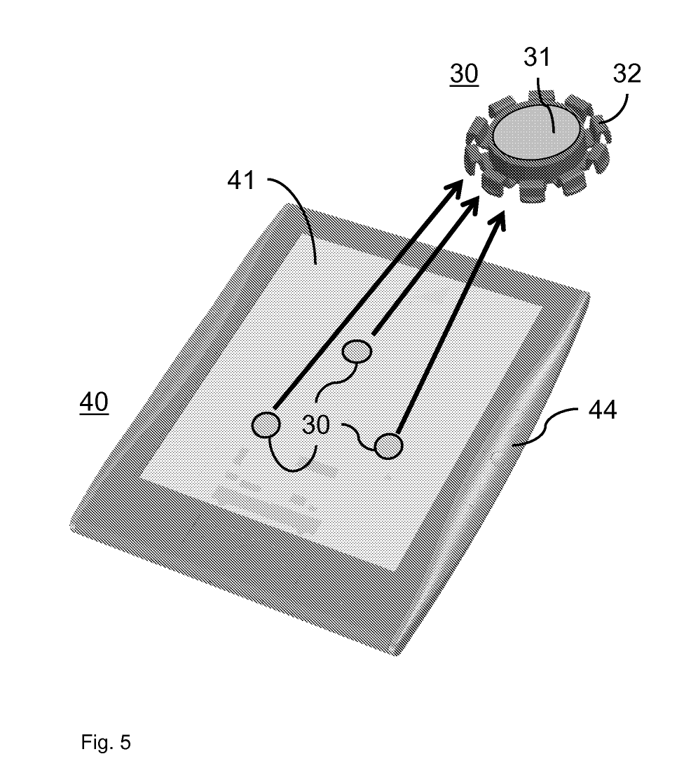

FIG. 5 indicates a preferred position for the display holders 30 to be used in a flat panel display 40. The flat panel display 40 is comprised in an E-book. It is to be noted that the display holders 30 may be used in a similar way for other devices comprising a flat panel display, such as a laptop, a TV, a cellular phone, a PDA or a computer monitor. In this E-book, three display holders 30 are used, which are symmetrically arranged around the display center. Of course, it is also possible to use four or more display holders 30. Using only one or two display holders 30 is also possible, but not preferable for taking full advantage of the invention. By placing the display holders 30 not too far away from the center of the display panel 41, also shocks in a direction perpendicular to the display panel 41 are absorbed. Consequently, breaking of the display panel 41 due to objects falling on the display panel 41 or a user pushing on the display panel very hard is prevented. In this arrangement, the display holders 30 thus provide good protection against shocks in all directions parallel and perpendicular to the plane, which makes the display 40 very robust.

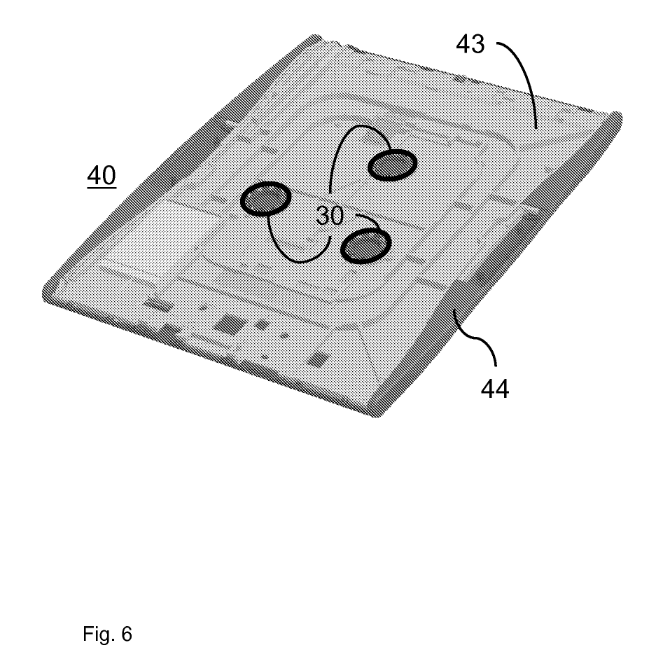

FIG. 6, shows the flat panel display 40 of FIG. 5, from a bottom view and during assemblage. The frame 43 is shown, with three display holders placed in the corresponding holes in the frame 43. The frame is placed in an external housing 44 of the display 40. When the display panel 41 is placed and aligned and the display holders 30 are attached to the display panel 41, the back of the frame 43 will be covered with the back part of the housing 44 (not shown) and the display will be ready for use.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

1. A display holder (10, 20, 30) for coupling a frame (43) of a flat panel display (40) to a display panel (41) of the flat panel display (40), the display holder (10, 20, 30) comprising a support surface (11, 21, 31) for supporting the display panel (41) and for attaching the display holder (10, 20, 30) to the display panel (41), the display holder (10, 20, 30) being constructed for being received by a hole in the frame (43), which hole is present in the frame (43) for receiving the display holder (10, 20, 30).

2. A display holder (10, 20, 30) as claimed in claim 1, further comprising a resilient element (12, 22, 32) for coupling the display holder (10, 20, 30) to the frame (43), the resilient element (12, 22, 32) being arranged for absorbing shocks in a direction substantially parallel to the display panel (41).

3. A display holder (10, 20, 30) as claimed in claim 1, wherein the support surface (11, 21, 31) comprises an adhesive.

4. A display holder (10, 20, 30) as claimed in claim 3, further comprising a release liner for covering the adhesive before assembly of the support surface (11, 21, 31) to the display panel (41).

5. A display holder (10, 20, 30) as claimed in claim 2, wherein the resilient element (12, 22, 32) comprises the support surface (11, 21, 31).

6. A device comprising a flat panel display (40) comprising:
a display panel (41), at least one display holder (10, 20, 30) as claimed in claim 1, and
a frame (43) for holding the display panel (41), the frame (43) comprising at least one hole for receiving the display holder (10, 20, 30), the hole being provided at a position suitable for supporting the display panel (41).

7. A device as claimed in claim 6, wherein the hole and the display holder (10, 20, 30) are configured to be combined in two exchangeable modes:
an operational mode, wherein the display holder (10, 20, 30) is attached to the display panel (41), and
an assembly mode, wherein the display holder (10, 20, 30) is not attached to the display panel (41).

8. A device as claimed in claim 6, wherein the frame (43) comprises three holes, each hole being configured for receiving a respective display holder (10, 20, 30).

9. A device as claimed in claim 8, wherein the holes are provided at three positions around a center of the display panel (41) for preventing bending of the display panel (41) in the event of shocks in a direction perpendicular to the display panel (41).

10. A frame (43) for use in a device as claimed in claim 6.

11. A method of assembling a device as claimed in claim 6, the method comprising the steps of:
placing the display panel (41) on the frame (43), pre-positioning the display holder (10, 20, 30) in the hole of the frame (43), aligning the display panel (41) relative to the frame (43), and
attaching the support surface (11, 21, 31) of the display holder (10, 20, 30) to the display panel (41).

12. A method of assembling as claimed in claim 11, further comprising:
detaching the support surface (11, 21, 31) from the display panel (41), re-aligning the display panel (41) relative to the frame (43), and
re-attaching the support surface (11, 21, 31) to the display panel (41).
